(19) United States
(12) Patent Application Publication
(10) Pub. No.: US 2005/0255677 A1
(43) Pub. Date: Nov. 17, 2005

(54) Integrated circuit with impurity barrier

(76) Inventors: Jason W. Weigold, Gilford, NH (US); Thomas D. Chen, Malden, MA (US); Denis Mel O'Kane, Somerville, MA (US); Claire N. Leveugle, Frankfield (IE); Stephen Alan Brown, Newtownards (GB); William A. Nevin, Portadown (GB)

Correspondence Address: Steven G. Saunders;Bromberg & Sunstein LLP, 125 Summer Street, Boston, MA, 02110-1618, US

(21) Appl. No.: 11/044,612

(22) Filed: Jan. 27, 2005

Related U.S. Application Data
(60) Provisional application No. 60/571,724, filed on May 17, 2004.

(51) Int. Cl. H01L 21/30

(52) U.S. Cl. 438/471

(57) ABSTRACT

An integrated circuit with an interface between a semiconductor layer (having a selected region) and a second layer has a barrier with a gettering effect that 1) substantially circumscribes the selected region and 2) extends to the interface. Despite the fact that its gettering effect extends to the interface, the barrier does not penetrate the second layer.

### PRIORITY

This patent application claims priority from provisional U.S. patent application No. 60/571,724, filed May 17, 2004 entitled, “IMPURITY LOCALIZER,” and naming Jason Weigold, Claire Leveugle, Thomas Chen, Stephen Brown, Denis O'Kane, and William Nevin as inventors, the disclosure of which is incorporated herein, in its entirety, by reference.

### FIELD OF THE INVENTION

The invention generally relates to integrated circuits and, more particularly, the invention relates to minimizing the impact of impurities in integrated circuits.

### BACKGROUND OF THE INVENTION

Impurities and defects in the silicon of an integrated circuit can significantly degrade device performance. For example, impurities and defects within integrated circuits having active circuitry can adversely affect gate oxide integrity, minority carrier lifetime, and leakage current. To minimize their impact, silicon-based devices often have internal gettering sites (e.g., oxygen precipitates) to collect impurities in a local, substantially innocuous area.

Some types of devices, such as those implemented on silicon-on-insulator wafers (“SOI wafers”), often cannot benefit from various types of gettering sites. Specifically, SOI wafers have an insulator layer positioned between a device layer having active circuitry and/or MEMS devices, and a handle layer. Often, the handle layer has gettering sites. Because the insulator layer acts as a barrier between the other two layers, however, the device layer cannot benefit from those gettering sites.

Moreover, SOI wafers have an additional, exposed interface between the insulator layer and the device layer. Undesirably, this interface can provide an additional path for contaminants to diffuse into active areas of the device layer, thus affecting circuitry or other components. Among other undesirable results, such diffusion can degrade circuit performance and long term reliability.

### SUMMARY OF THE INVENTION

In accordance with one aspect of the invention, an integrated circuit with an interface between a semiconductor layer (having a selected region) and a second layer has a barrier with a gettering effect that 1) substantially circumscribes the selected region and 2) extends to the interface. Despite the fact that its gettering effect extends to the interface, the barrier does not penetrate the second layer.

To provide the gettering effect, the barrier may extend to the interface, or be spaced from the interface. In some embodiments, the semiconductor layer has a top surface from which the barrier extends. Among other things, the second layer may be an insulator layer of a silicon-on-insulator wafer. The selected region may have a number of components, such as circuitry.

The barrier may be in the form of a trench at least partially filled with polysilicon. Alternatively, the barrier may be in the form of an implant. In addition, the barrier may be continuous, or discontinuous.

In accordance with another aspect of the invention, a method of forming an integrated circuit first provides an apparatus having a semiconductor layer that meets a second layer at an interface, and then forms a barrier in the semiconductor layer. The barrier produces a gettering effect that extends to the interface. The barrier nevertheless does not penetrate the second layer. The gettering effect substantially circumscribes a selected region of the semiconductor layer.

The barrier may be formed by a number of methods. For example, the barrier may be formed by forming a trench and at least partially filling the trench with a material. Alternatively, the barrier may be formed by injecting an implant into the semiconductor layer. The barrier may extend to, or be spaced from, the interface.

### BRIEF DESCRIPTION OF THE DRAWINGS

The foregoing and advantages of the invention will be appreciated more fully from the following further description thereof with reference to the accompanying drawings wherein:

FIG. 1 schematically shows a packaged integrated circuit that may be produced in accordance with illustrative embodiment of the invention.

FIG. 2 schematically shows a plan view of the integrated circuit of FIG. 1 formed in accordance with illustrative embodiments of the invention.

FIG. 3 schematically shows a plan view of the integrated circuit of FIG. 1 formed in accordance with alternative embodiments of the invention.

FIG. 4 shows a process of forming the integrated circuit of FIG. 1 in accordance with illustrative embodiments of the invention.

FIG. 5 schematically shows a cross-sectional view of one embodiment of the integrated circuit shown in FIG. 2 along line X-X.

FIG. 6 schematically shows a cross-sectional view of another embodiment of the integrated circuit shown in FIG. 2 along line X-X.

### DESCRIPTION OF ILLUSTRATIVE EMBODIMENTS

In illustrative embodiments, a multi-layer integrated circuit/chip substantially limits the ability of impurities from traversing along portions of the interface between at least two of its adjacent layers. To that end, the integrated circuit has a barrier that produces a substantially continuous gettering effect about a selected region of the chip. Although its gettering effect extends to the interface, the barrier itself does not extend beyond a single layer and, in fact, may not even extend to the interface. Details of illustrative embodiments are discussed below.

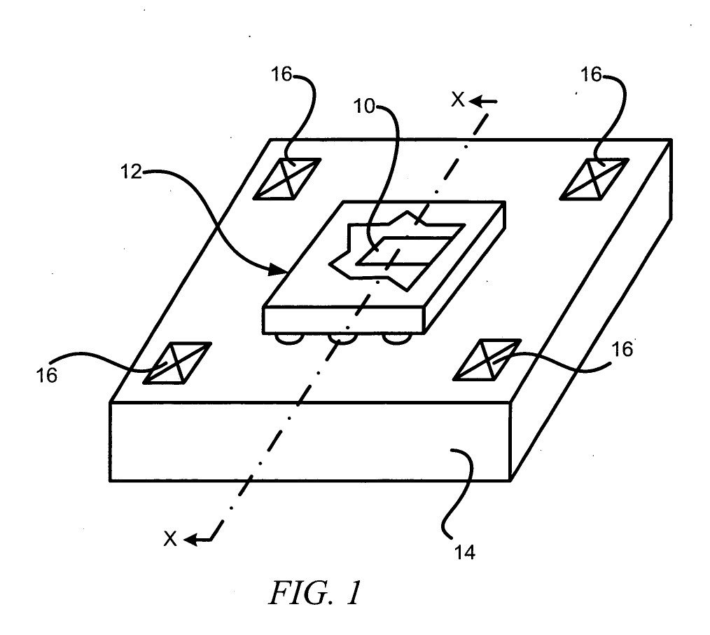

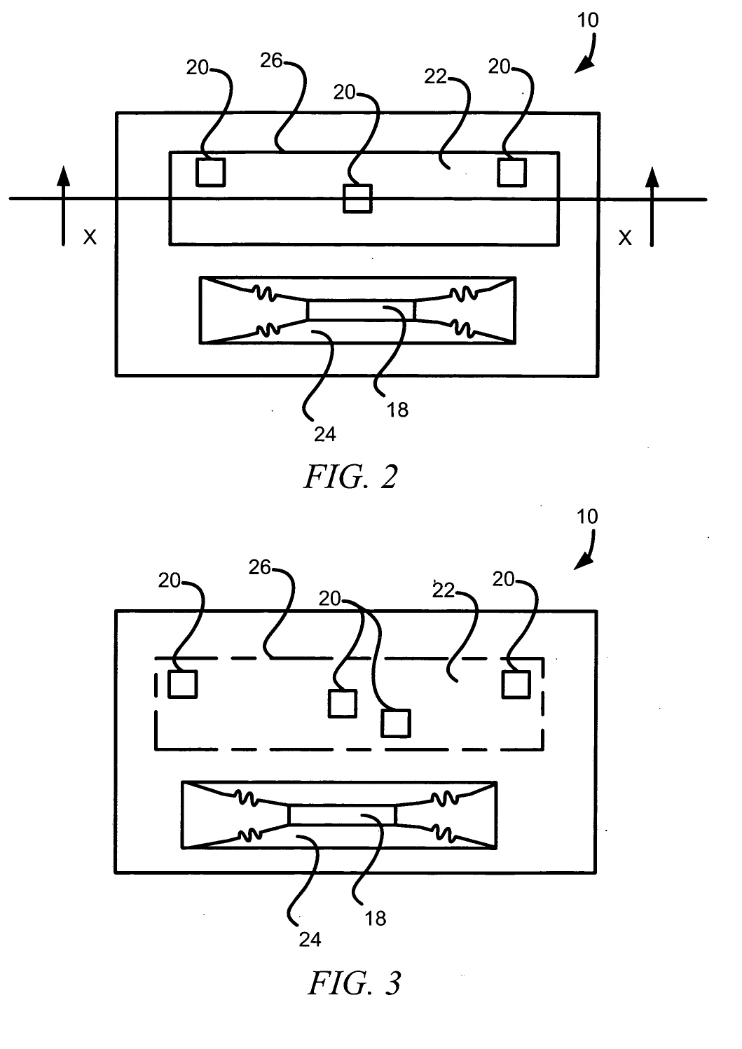

FIG. 1 schematically shows an exemplary packaged integrated circuit chip (referred to herein as “integrated circuit 10” or “chip 10”) that may be produced in accordance with illustrative embodiments of the invention. Specifically, the integrated circuit 10 in this embodiment is a MEMS device having both circuitry 20 and movable structure 18 (see FIGS. 2 and 3). The integrated circuit 10 illustratively is formed on a silicon-on-insulator wafer (“SOI,” shown in cross-section in subsequent figures) and packaged within a conventional ceramic package 12. The package 12 is coupled with a circuit board 14 having interconnects 16 to electrically communicate with an external device, such as a computer.

If implemented as a MEMS device, the integrated circuit 10 may execute any conventionally known functionality commonly implemented on a MEMS device, such as an inertial sensor. For example, the integrated circuit 10 may be a gyroscope or an accelerometer. Exemplary MEMS gyroscopes are discussed in greater detail in U.S. Pat. No. 6,505,511, which is assigned to Analog Devices, Inc. of Norwood, Mass. Exemplary MEMS accelerometers are discussed in greater detail in U.S. Pat. No. 5,939,633, which also is assigned to Analog Devices, Inc. The disclosures of U.S. Pat. Nos. 5,939,633 and 6,505,511 are incorporated herein, in their entireties, by reference.

Although the packaged integrated circuit 10 is discussed as a MEMS inertial sensor, principles of illustrative embodiments can apply to other integrated circuits, such as pressure sensors and microphones (e.g., MEMS pressure sensors or MEMS inertial sensors). Accordingly, discussion of an inertial sensor is exemplary and not intended to limit the scope of various embodiments of the invention.

Moreover, alternative embodiments include integrated circuits formed by processes other than SOI. For example, conventional surface micromachining (“SMM”) techniques may form the integrated circuit 10. As known by those skilled in the art, surface micromachining techniques build material layers on top of a substrate (e.g., a single crystal wafer) using additive and subtractive processes. As a further example, conventional SCREAM processes can form the MEMS device. SCREAM is the acronym for “single crystal reactive etching and metallization” processes, developed at Cornell University in 1993.

It should be noted, however, that discussion of MEMS devices is exemplary. Accordingly, principles of illustrative embodiments may apply to other types integrated circuits.

FIG. 2 schematically shows a plan view of the integrated circuit 10 of FIG. 1 formed in accordance with illustrative embodiments of the invention. Specifically, the integrated circuit 10 in this embodiment includes movable MEMS structure 18, and circuitry 20 for actuating and detecting movement of the structure 18. The structure 18 and circuitry 20 in this embodiment are located in two separate regions; namely, a circuit region 22 having circuitry 20, and a structure region 24 having MEMS structure 18. In some embodiments, however, the structure and circuit regions 24 and 22 may have overlapping footprints.

If the integrated circuit 10 implements a gyroscope, for example, the circuitry 20 may have actuation components for oscillating a movable mass, and detection components for detecting mass movement. Although the structure 18 and circuitry 20 are shown schematically, they may be similar to corresponding components known by those skilled in the art. For example, such structure 18 and circuitry 20 may be similar to those disclosed in the incorporated patents.

In accordance with illustrative embodiments of the invention, the integrated circuit 10 has a barrier 26 to protect the circuitry 20 from impurities, such as metals produced during a wafer singulation process. When shown from the top view, the barrier 26 shown in FIG. 2 circumscribes the circuit region 22. It should be noted, however, that discussion of metals produced during the wafer singulation process is exemplary of illustrative embodiments only. Accordingly, various embodiments protect against impurities introduced at other times.

FIG. 3 shows an alternative embodiment of the invention. Specifically, in a manner similar to the integrated circuit 10 in FIG. 2, the integrated circuit 10 in FIG. 3 also has a circuit region 22 and structure region 24. This integrated circuit 10 differs from that shown in FIG. 2, however, because its barrier 26 around the circuit region 22 is discontinuous. Notwithstanding this difference, both barriers 26 should function substantially identically; namely, both barriers 26 produce a gettering effect that substantially prevents many impurities from passing into the circuit region 22. In fact, this gettering effect should block impurities from penetrating the circuit region 22 via the device layer interface 34. To those ends, as discussed in greater detail below, this gettering effect should extend to the device layer interface 34 and circumscribe the circuit region 22.

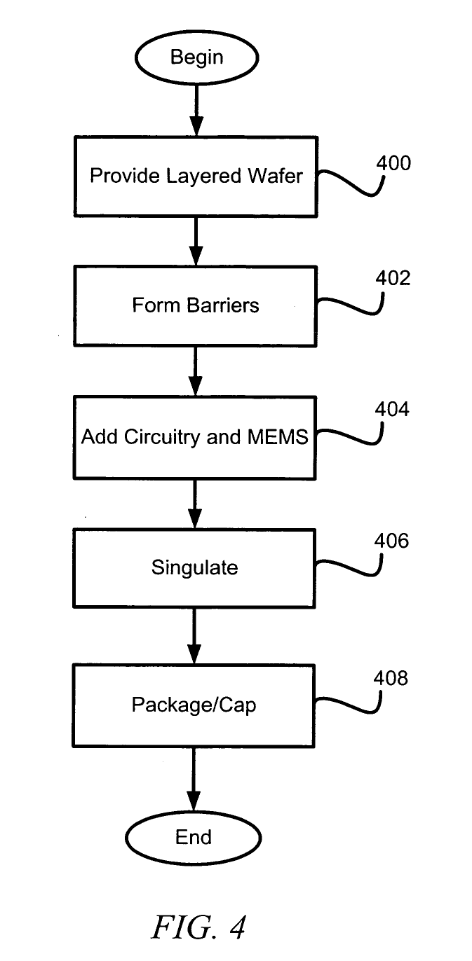

FIG. 4 shows a process of producing an integrated circuit 10, such as those shown in FIGS. 2 and 3, in accordance with illustrative embodiments of the invention. It should be noted that the process discussed with regard to FIG. 4 is not intended to be complete with regard to all possible steps for producing an integrated circuit 10. Instead, the process highlights various important steps for implementing illustrative embodiments of the invention. In addition, some of the steps of the process can be executed in a different order, or at substantially the same time (e.g., steps 402-404, discussed below).

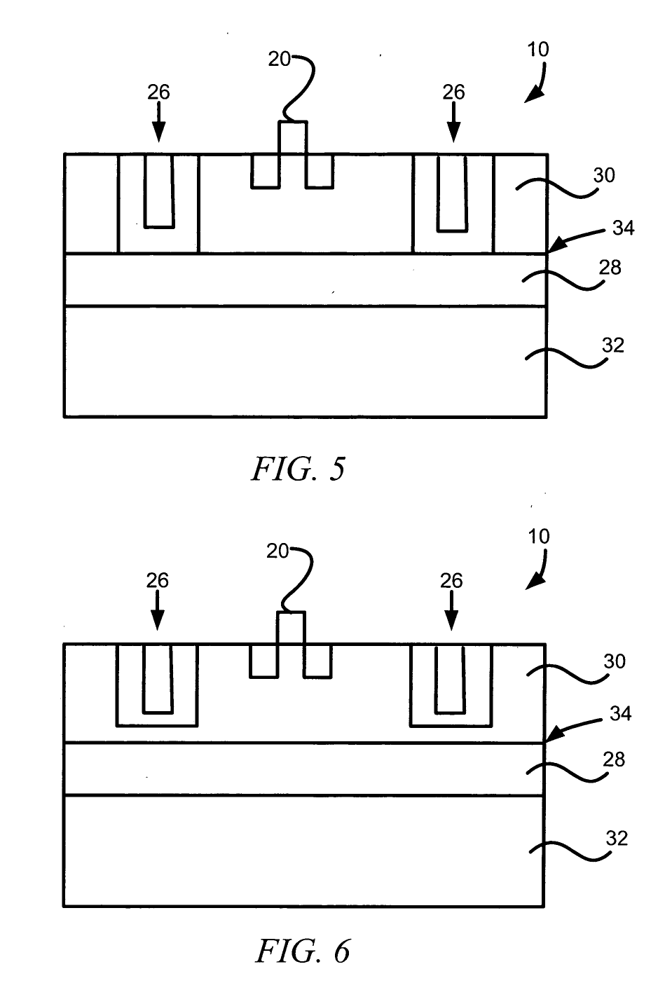

The process begins at step 400, which provides a layered wafer. This layered wafer may be any conventionally produced wafer, such as a SOI wafer. As known by those in the art, a SOI wafer has an insulator layer 28 between two silicon layers (see FIGS. 5 and 6). One of the two silicon layers, often referred to as a “device layer 30” or “top layer 30,” contains the MEMS structure 18 and/or circuitry 20. The other silicon layer, often referred to as a “handle layer 32” or “bottom layer 32” and generally much thicker than the device layer 30, acts as a support substrate.

The SOI wafer has at least two interfaces—the interface between the device layer 30 and the insulator layer 28, and the interface between the insulator layer 28 and the handle layer 32. Those interfaces, as well as the discussed layers, are shown in FIGS. 5 and 6, which show cross-sectional views of two embodiments of the invention. As discussed herein, the barriers 22 shown in FIGS. 2, 3, 5, and 6 substantially prevent impurities from entering the circuit region 22 via the interface between the device layer 30 and the insulator layer 28 (hereinafter, “device layer interface 34”).

The wafers may be formed by other processes. For example, the wafer could have a silicon base carrying one or more other layers formed from some other material (e.g., polysilicon, silicon germanium, oxide, etc . . . ). Accordingly, illustrative embodiments may provide one of these alternative wafers.

This process illustratively forms a plurality of chips 10 from a single wafer. Accordingly, the process then continues to step 402, which forms an array of barriers 22 around wafer regions that ultimately will be circuit regions 22 of separate chips 10. FIG. 5 schematically shows a cross-sectional view of one embodiment, in which the barrier 26 of one chip 10 extends from the top surface to the device layer interface 34. Although it extends to the insulator layer 28, the barrier 26 does not extend into or in any way (in a non-negligible manner) penetrate the insulator layer 28. In a similar manner, FIG. 6 schematically shows a cross-sectional view of another embodiment, in which the barrier 26 does not extend to the device layer interface 34. It should be noted that in some embodiments, the barrier 26 also does not extend from the top surface of the device layer 30.

Those in the art should understand that in both embodiments shown in FIGS. 5 and 6, there may be physical spaces between the barrier 26 and the top face of the insulator layer 28. The spaces between the barrier 26 and top face of the insulator layer 28 should be much smaller in the embodiment shown in FIG. 5 than those shown in FIG. 6. The barrier 26 nevertheless prevents impurities from entering the circuit region 22 through this space because, in addition to acting as a physical barrier, the barrier 26 produces a gettering effect that draws impurities to it. This draw should substantially prevent a significant amount of impurities from entering the circuit region 22.

As noted above, in illustrative embodiments, this gettering effect extends circumferentially around the circuit region 22 (FIGS. 2 and 3) and extends through the integrated circuit 10 to the device layer interface 34 (FIGS. 5 and 6). To limit the likelihood that gettered impurities affect circuitry 20 in the circuit region 22, the circuitry 20 preferably is in a region that is not too close to the barrier 26. This distance can be empirically determined, or determined based upon the properties of the barrier 26.

When implementing the embodiment shown in FIG. 6, a circuit designer could examine the gettering effect of prototypes to determine its effectiveness. After determining the appropriate spacing (between the device layer interface 34 in the barrier 26), the designer may extend the barrier 26 to be slightly closer to the device layer interface 34 to further ensure performance. Of course, this design still should not extend barrier 26 into the insulator layer 28.

The barrier 26 may be formed in a number of ways that perform the desired effect. For example, a trench filled with some material should suffice. Among other things, the material may be polysilicon, metal, or nitride. If the integrated circuit 10 subsequently will be subjected to high temperature processes (e.g., greater than about 400 degrees C.), then metal should not be used. In these cases, polysilicon should provide satisfactory results. To those ends, the trench may be formed and filled in accordance with conventional processes.

Rather than take the form of a filled trench, the barrier 26 may be an implant (e.g., boron) that is driven down to the device layer interface 34 from the top surface. It should be noted that the implant may be any material sufficient for the discussed purposes. For example, the implant may be a molecule, species, ion, or other material. In addition, some embodiments drive the implant upwardly into the device layer 30 (toward the top surface) from the device layer interface 34. In these discussed alternatives, the barrier 26 should apply a stress to the device layer 30 that effectively getters impurities. Of course, as noted above, various embodiments are not limited to the type of barrier that is used. Instead, the barrier 26 can be produced by any conventional means that delivers a sufficient gettering effect. For example, rather than applying a local stress to produce a gettering affect, some embodiments may damage the crystalline layer.

Returning to FIG. 4, after the array of barriers 26 are formed, the process continues to step 404, which adds circuitry 20 and/or MEMS structure 18 to the wafer. Some impurities already within the silicon should migrate more rapidly toward the barriers 26 if high temperature processes form the circuitry 20 and/or MEMS structure 18. As noted above, the MEMS structure 18 and circuitry 20 may be formed in accordance with conventional processes, such as those in the incorporated patents.

After the circuitry 20 and MEMS structure 18 are formed, then the process continues to step 406, which singluates the wafer. Conventional sawing/dicing processes may be used. Of course, as known by those skilled in the art, sawing/dicing can produce additional impurities, such as metal fragments, into the individual chips 10. The barriers 26, however, should protect against these additional impurities. Finally, the process ends by packaging and/or capping the integrated circuit 10 in a conventional package 12. For example, the integrated circuit 10 may be packaged in a conventional plastic package, premolded package, or ceramic package.

Accordingly, illustrative embodiments of the invention form a barrier 26 on an integrated circuit 10 in a manner that substantially prevents impurities from affecting its circuitry 20. Although such a barrier 26 may extend to (but not penetrate) an adjacent layer, its gettering effect should accomplish the intended function-namely, substantially preventing impurities from penetrating into the region containing circuitry 20.

Moreover, forming the barrier 26 in this manner eliminates various fabrication steps required in prior art barriers by not penetrating adjacent layers. Specifically, prior art processes may require additional processing steps to etch into an adjacent layer. Consequently, because various embodiments eliminate that necessity, integrated circuits having the described barrier 26 may be more efficiently produced at a lower cost.

Although the above discussion discloses various exemplary embodiments of the invention, it should be apparent that those skilled in the art can make various modifications that will achieve some of the advantages of the invention without departing from the true scope of the invention.

1. An integrated circuit comprising:
a semiconductor layer having selected region; and
a second layer, the semiconductor layer and second layer meeting at an interface; and
a barrier for producing a gettering effect in the semiconductor layer, the gettering effect extending to the interface, the barrier not penetrating the second layer,
the gettering effect substantially circumscribing the selected region.

2. The integrated circuit as defined by claim 1 wherein the barrier extends to the interface.

3. The integrated circuit as defined by claim 1 wherein the barrier is spaced from the interface.

4. The integrated circuit as defined by claim 1 wherein the semiconductor layer has a top surface and a bottom surface, the barrier extending from one of the top surface or the bottom surface.

5. The integrated circuit as defined by claim 1 wherein the second layer comprises an insulator of a silicon-on-insulator wafer.

6. The integrated circuit as defined by claim 1 wherein the barrier comprises a trench at least partially filled with polysilicon.

7. The integrated circuit as defined by claim 1 wherein the barrier comprises an implant.

8. The integrated circuit as defined by claim 1 wherein the barrier is discontinuous.

9. The integrated circuit as defined by claim 1 wherein the selected region has circuitry.

10. An integrated circuit comprising:
a semiconductor layer having selected region; and
a second layer, the semiconductor layer and second layer meeting at an interface; and
means for producing a gettering effect that extends to the interface, the producing means not penetrating the second layer,
the gettering effect substantially circumscribing the selected region.

11. The integrated circuit as defined by claim 10 wherein the producing means includes a trench filled with a material.

12. The integrated circuit as defined by claim 10 wherein the producing means extends to the interface.

13. The integrated circuit as defined by claim 10 wherein the producing means is spaced from the interface.

14. The integrated circuit as defined by claim 10 wherein the semiconductor layer has a top surface, the producing means extending from the top surface.

15. A method of forming an integrated circuit, the method comprising:
providing an apparatus comprising a semiconductor layer that meets a second layer at an interface; and
forming a barrier in the semiconductor layer, the barrier producing a gettering effect that extends to the interface, the barrier not penetrating the second layer,
the gettering effect substantially circumscribing a selected region of the semiconductor layer.

16. The method as defined by claim 15 wherein forming comprises forming a trench and at least partially filling the trench with a material.

17. The method as defined by claim 15 wherein forming comprises injecting an implant into the semiconductor layer.

18. The method as defined by claim 15 wherein the barrier is formed to extend to the interface.

19. The method as defined by claim 15 wherein the barrier is formed to be spaced from the interface.

20. The apparatus formed by the process defined by claim 15.
